(19) United States
(12) Patent Application Publication
(10) Pub. No.: US 2009/0232325 A1
(43) Pub. Date: Sep. 17, 2009

(54) REACTIVE HEADPHONES

(76) Inventor: Johan LUNDQUIST, Lund (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(21) Appl. No.: 12/046,505

(22) Filed: Mar. 12, 2008

(51) Int. Cl. H04R 1/10; H03G 3/20

(52) U.S. Cl. 381/74; 381/57; 381/370

(57) ABSTRACT

A method and apparatus for monitoring environmental noise when a user is listening to audio signals via headphones is disclosed. When an audio input signal is received, the audio input signal is transmitted to speakers in the headphones. A noise input signal from environment around the headphones is received and analyzed for predetermined sounds. The transmission of the audio input signal is stopped when predetermined noise characteristics are detected in the noise input signal.

### TECHNICAL FIELD OF THE INVENTION

The present invention relates to headphones and more particularly to a method and apparatus for monitoring environmental noise when a user is listening to an audio signal via headphones.

### DESCRIPTION OF RELATED ART

In the past 20 years, MP3 players, IPODS, and mobile phones have made it very easy for people to carry music with them where ever they go. As a result, more and more people are listening to their music as they travel throughout their day. Usually, these people use headphones to listen to their music. As a result, people tend not to be able to hear sounds that are going on around them. Normally, this is not a big problem since most of the surrounding sounds are sounds that the music listener does not want to hear. These surrounding sounds include people talking, children playing, busy street noise and construction noise. There are, however, sounds that are important but are missed because the person is listening to their music. These sounds may be a friend shouting the person's name or a car honking when the music listener is trying to cross a street.

The headphones available on the market today are passive in the sense that they either transmit sound or they do not transmit sound. The user of the headphones decides whether the headphones are on or off. There are also passive and active ear protections available on the market today. The passive system simply block out every sound. The active systems let soft sounds pass while loud and abrupt sounds are blocked out. As a result, these active systems will block out the type of sounds that the music listener may need to hear for safety or convenience.

Thus, there is a need for a method and apparatus for monitoring environmental noise when a user is listening to an audio signal via headphones wherein the audio signal is paused to allow the user to hear certain environmental noise.

### SUMMARY OF THE INVENTION

According to some embodiments of the invention, a method for monitoring environmental noise when a user is listening to audio signals via headphones, comprising the steps of: receiving an audio input signal; transmitting the audio input signal to speakers in the headphones; receiving noise input signal from environment around the headphones; analyzing said noise input signal for predetermined sounds; stopping transmission of the audio input signal when predetermined noise characteristics are detected in the noise input signal.

According to another embodiment of the invention, an active sound system, comprising: an audio input for receiving an audio input signal; a transmitter for transmitting the audio input signal to speakers in headphones; a microphone for receiving a noise input signal from the environment around the headphone; a computing system for detecting the presence of predetermined noise characteristics in said noise input signal, wherein transmission of the audio input signal is stopped when the predetermined noise characteristics are present.

According to another embodiment of the invention, a computer readable medium storing code for monitoring environmental noise when a user is listening to audio signals via headphones, comprising: code for receiving an audio input signal; code for transmitting the audio input signal to speakers in the headphones; code for receiving a noise input signal from environment around the headphones; code for analyzing said noise input signal for predetermined sounds; code for stopping transmission of the audio input signal when predetermined noise characteristics are detected in the noise input signal.

Further embodiments of the invention are defined in the dependent claims.

It is an advantage of embodiments of the invention that an audio signal will be paused when it is determined that the audio signal listener needs to hear environmental noise.

### BRIEF DESCRIPTION OF THE DRAWINGS

Further objects, features and advantages of embodiments of the invention will appear from the following detailed description of the invention, reference being made to the accompanying drawings, in which:

FIG. 1 illustrates an audio system for use by the invention;

FIG. 2 illustrates a active sound system according to one embodiment of the invention; and

FIG. 3 is a flow chart describing the operation of the active sound system according to one embodiment of the invention; and

FIG. 4 is a computer system for implementing one embodiment of the invention.

### DETAILED DESCRIPTION OF EMBODIMENTS

Specific illustrative embodiments of the invention will now be described with reference to the accompanying drawings. This invention may, however, be embodied in many different forms and should not be construed as limited to the embodiments set forth herein. Rather, the disclosed embodiments are provided so that this specification will be thorough and complete, and will fully convey the scope of the invention to those skilled in the art. The terminology used in the detailed description of the particular embodiments illustrated in the accompanying drawings is not intended to be limiting of the invention. Furthermore, in the drawings like numbers refer to like elements.

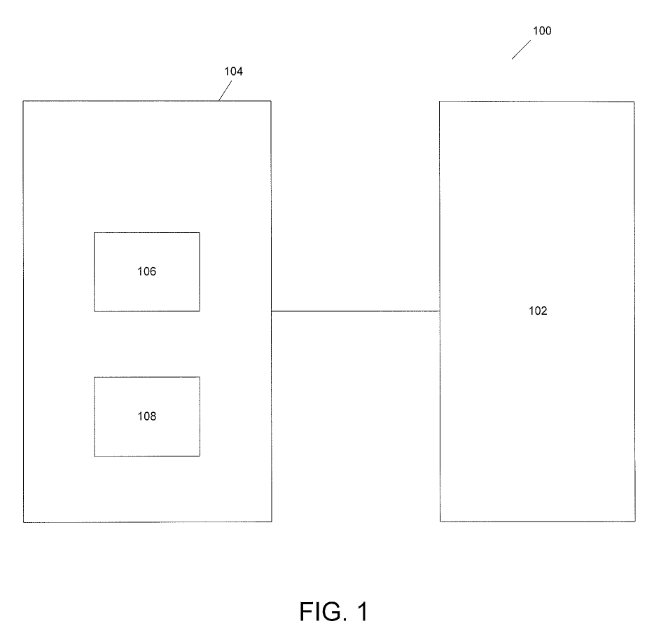

FIG. 1 illustrates an audio system 100 within which the invention may operate. The audio system 100 comprises a portable music device 102 such as a MP3 player, IPOD, mobile phone, computer. The audio system 100 also comprises headphones 104. The headphones 104 comprises at least speakers 106. The audio system also comprises an active sound system 108. The active sound system 108 can be located in the headphones 104 or the music device 102.

According to one embodiment of the invention, the active sound system 108 determines if predetermined sounds, e.g., a car horn, someone yelling your name, etc. are detected in the environment around a person using headphones. As will be explained in more detail below, the predetermined sounds can be detected by a filter and/or a noise recognition system and the invention is not limited thereto.

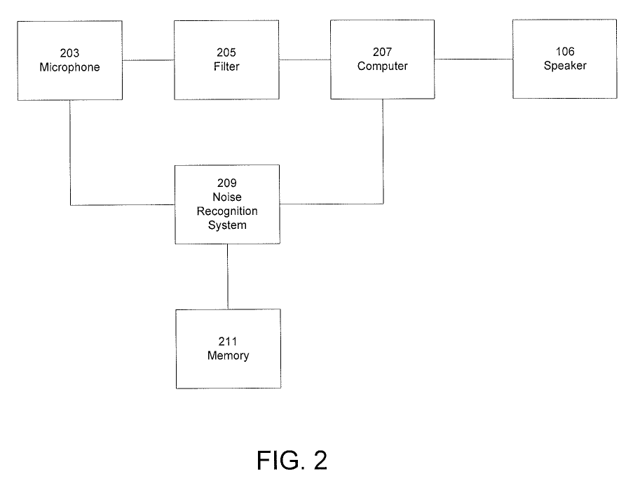

As illustrated in FIG. 2, the active sound system 108 is comprised of a microphone 203, a filter 205, a computer 207, a noise recognition system 209 and a memory 211 but the invention is not limited thereto. For example, the active sound system 108 may only comprise the microphone 203, the filter 205 and the computer 207. Likewise, the active sound system 108 may only comprise the microphone 203, the noise recognition system 209, the memory 211 and the computer 207.

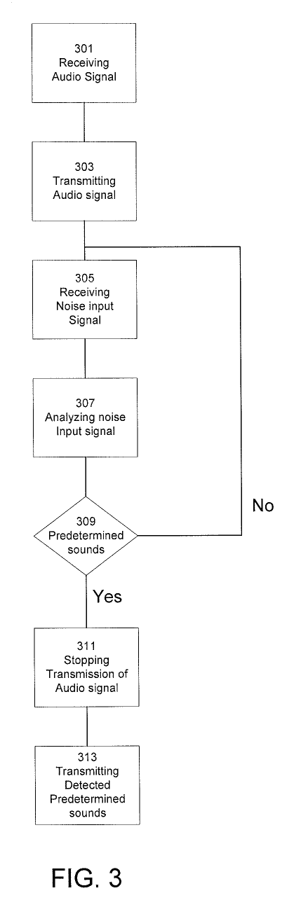

The operation of the active sound system 108 will now be explained with reference to FIG. 3. As described above, an audio input signal, such as a music signal, is generated by the music device 102 in a known manner. The audio input signal is received by the computer 207 in step 301. The computer then transmits the audio input signal to the speakers 106 in the headphones 104 for a person to hear in step 303. While the audio input signal is playing, the microphone 203 generates a noise input signal from sounds detected in the vicinity of the microphone 203 in step 305. As mentioned above, the microphone 203 can be located in the headphones 104 or the music device 102 and the invention is not limited thereto.

The received noise input signal is analyzed by the active sound system 201 in step 307 to determine if the received noise input signal contains a predetermined sound or sounds. The active sound system 201 may analyze the received noise input signal in several ways to determine if the noise input signal contains at least one predetermined sound. First, the received noise input signal may be filtered by the filter 205. The filter 205 can be designed to let through sounds above a predetermined frequency, above a predetermined volume level, and/or between several predetermined frequency levels and the invention is not limited thereto. If a signal remains after being filtered by the filter 205, the computer 207 determines that at least one predetermined sound is present in the received noise input signal in step 309.

In addition or alternatively, the active sound system 201 may analyze the received noise input signal using the noise recognition system 209. In this embodiment, the received noise input signal is compared with predetermined sounds which are stored in the memory 211. These predetermined sounds comprise names, words, phrases, car horn noises, emergency siren noises, animal noises and the invention is not limited thereto. Furthermore, the predetermined sounds can be user dependent. For example, the user can select which sounds should be stored and then compared to the received noise input signal. This includes the user's name as well as other noises depending on the user's preferences. For example, some people might not want to hear a crying baby, but other people, such as new parents, may want to hear the crying baby. By making the stored sounds user dependent, each user can tailor the active noise system 201 to their particular needs.

If the computer 207 detects the presence of predetermined sounds in the received noise input signal from either the filter 205 and/or the noise recognition system 209 in step 309, the computer 207 stops the transmission of the audio input signal to the speakers 106 in step 311. By stopping the transmission of the audio input signal to the speakers 106, the audio input signal will now not interfere with the user's ability to hear the noise in the environment around the user. As a result, the user will now be able to hear warnings or shouts or whatever noise the user has specified that he/she wants to hear.

According to another embodiment of the invention, the active sound system 201 can be used to help the user hear preselected sounds when they occur by sending the received preselected sounds to the speakers 106 in the headphones 104. In this embodiment, when the computer 207 stops the transmission of the audio input signal in step 311, the computer then sends the part of the received noise input signal containing preselected sounds to the speakers 106 in step 313.

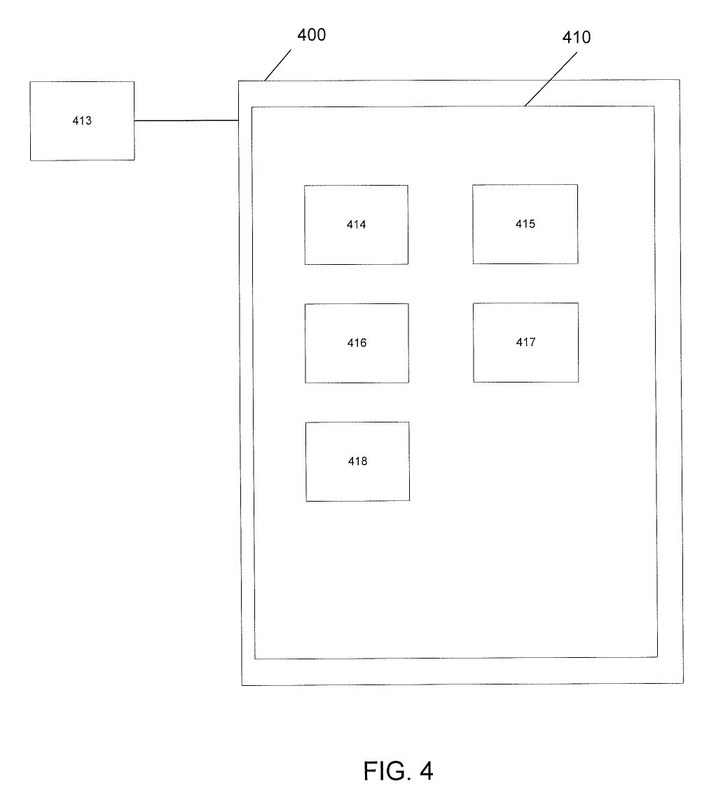

In another embodiment of the invention according to FIG. 4, a computer-readable medium 400 is illustrated schematically. The computer-readable medium 400 has embodied thereon a computer program 410 for monitoring environmental noise, for processing by a computer 413. The computer program comprises a code segment 414 for receiving an audio input signal, a code segment 415 for transmitting the audio input signal to speakers in the headphones, a code segment 416 for receiving a noise input signal from environment around the headphones, a code segment 417 for analyzing said noise input signal for predetermined sounds; and a code segment 418 for stopping transmission of the audio input signal when predetermined noise characteristics are detected in the noise input signal.

The present invention has been described above with reference to specific embodiments. However, other embodiments than the above described are equally possible within the scope of the invention. Different method steps than those described above, performing the method by hardware or software or a combination of hardware and software, may be provided within the scope of the invention. It should be appreciated that the different features and steps of the invention may be combined in other combinations than those described. The scope of the invention is only limited by the appended patent claims.

What is claimed is:

1. A method for monitoring environmental noise when a user is listening to audio signals via headphones, comprising the steps of:
receiving an audio input signal;
transmitting the audio input signal to speakers in the headphones;
receiving a noise input signal from environment around the headphones;
analyzing said noise input signal for predetermined sounds;
stopping transmission of the audio input signal when predetermined noise characteristics are detected in the noise input signal.

2. The method according to claim 1, wherein the steps of analyzing said noise input signal comprises the step of:
filtering said noise input signal using a predetermined filter to detect the presence of predetermined sounds in said noise input signal, wherein transmission of the audio input signal is stopped when the predetermined noise characteristics are present.

3. The method according to claim 2, wherein the predetermined sounds are any sounds above a predetermined frequency.

4. The method according to claim 2, wherein the predetermined sounds are any sounds above a predetermined decibel level.

5. The method according to claim 1, wherein the steps of analyzing said noise input signal comprises the step of:
comparing the noise input signal with stored predetermined noises characteristics, wherein transmission of the audio input signal is stopped when the predetermined noise characteristics are present.

6. The method according to claim 5, wherein the stored predetermined noise characteristics are user dependent.

7. The method according to claim 6, wherein the stored predetermined noises characteristics comprise, names, words, car horn noises, emergency sirens noises, animal noises.

8. The method according to claim 1, wherein the steps of analyzing said noise input signal comprises the step of:
filtering said noise input signal using a predetermined filter to detect the presence of predetermined noise characteristics in said noise input signal;
comparing the noise input signal with stored predetermined noises characteristics, wherein transmission of the audio input signal is stopped when the predetermined noise characteristics are present.

9. The method according to claim 1, further comprising the steps of:
transmitting detected predetermined sounds to the speakers in the headphones when the audio input signal is stopped.

10. An active sound system, comprising:
an audio input for receiving an audio input signal;
a transmitter for transmitting the audio input signal to speakers in headphones;
a microphone for receiving a noise input signal from the environment around the headphone;
a computing system for detecting the presence of predetermined noise characteristics in said noise input signal, wherein transmission of the audio input signal is stopped when the predetermined noise characteristics are present.

11. The active sound system according to claim 10, wherein the computer system comprises:
a filter for analyzing said noise input signal to detect the presence of predetermined sounds in the noise input signal, wherein a processor stops the transmission of the audio input signal when the predetermined sounds are present.

12. The active sound system according to claim 11, wherein the predetermined sounds are any sounds above a predetermined frequency.

13. The active sound system according to claim 11, wherein the predetermined sounds are any sounds above a predetermined decibel level.

14. The active sound system according to claim 10, wherein the computer system comprises:
a noise recognition system for comparing the noise input signal with predetermined sounds stored in a memory;
a processor for stopping the transmission of the audio input signal when the predetermined sounds are present.

15. The active sound system according to claim 14, wherein the stored predetermined sounds are user dependent.

16. The active sound system according to claim 15, wherein the stored predetermined sound comprises names, words, car horn noises, emergency siren noises, animal noises.

17. The active sound system according to claim 10, wherein the computer system comprises:
a filter for filtering said noise input signal to detect the presence of predetermined sounds in said noise input signal;
a noise recognition system for comparing the noise input signal with predetermined sounds stored in a memory, wherein a processor stops the transmission of the audio input signal when the predetermined sounds are present.

18. The active sound system according to claim 10, wherein the active sound system is located in the headphones.

19. The active sound system according to claim 10, wherein the active sound system is located in an external electronic device which is in communication with the headphone.

20. The active sound system according to claim 19, wherein the external electronic device is a mobile phone, MP3 player, or a computer.

21. The active sound system according to claim 10, wherein the computer system transmits the detected predetermined sounds to the speakers in the headphones when the audio input signal is stopped.

22. A computer readable medium storing code for monitoring environmental noise when a user is listening to audio signals via headphones, comprising:
code for receiving an audio input signal;
code for transmitting the audio input signal to speakers in the headphones;
code for receiving a noise input signal from environment around the headphones;
code for analyzing said noise input signal for predetermined sounds;
code for stopping transmission of the audio input signal when predetermined noise characteristics are detected in the noise input signal.
